(19) United States
(12) Patent Application Publication
(10) Pub. No.: US 2026/0161864 A1
(43) Pub. Date: Jun. 11, 2026

(54) HIERARCHICAL DESIGN CONNECTIVITY CHECKING

(71) Applicant: International Business Machines Corporation, Armonk, NY (US)

(72) Inventors: Christopher Jaeschke, Tuebingen (DE); Nitin Pundir, Cedar Park, TX (US); Maya Safieddine, Pflugerville, TX (US); Gabor Drasny, Poughkeepsie, NY (US); Claudia Wolkober, Bondorf (DE); Ulla Herter, Stuttgart (DE); Markus Dobler, Holzgerlingen (DE); Ali S. El-Zein, Austin, TX (US); Viresh Paruthi, Austin, TX (US); Ralf Maier, Bempflingen (DE)

(21) Appl. No.: 18/971,845

(22) Filed: Dec. 6, 2024

(51) Int. Cl. G06F 30/33

(52) U.S. Cl. CPC G06F 30/33

(57) ABSTRACT

Hardware definition language source files for building a circuit model is loaded into computer memory. The hardware definition language source files are compiled into the circuit model. Responsive to the hardware definition language source file loading and compiling, files that define labels for circuit components of the circuit model are automatically loaded into the computer memory. The labels for circuit components are read from the files. The circuit components of the circuit model are marked with the labels that respectively correspond to the circuit components. Correctness of structural connections among the circuit components of the circuit model is checked by traversing the circuit model based on the marked circuit components and checking against preconfigured rules of connectivity among the circuit components.

### BACKGROUND

The present application relates to processor design, processor or circuit structural and connectivity testing and checks, and more particularly to formalizing circuit design connectivity checking via interface specification tags.

### BRIEF SUMMARY

The summary of the disclosure is given to aid understanding of a computer system and method of processor structural and connectivity design checks, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the computer system and/or their method of operation to achieve different effects.

In some embodiments, a method includes loading into computer memory hardware definition language source files for building a circuit model. The method also includes compiling the hardware definition language source files into the circuit model. The method also includes, responsive to the hardware definition language source file loading and compiling, automatically loading into the computer memory, files that define labels for circuit components of the circuit model. The method also includes reading from the files the labels for circuit components. The method also includes marking the circuit components of the circuit model with the labels that correspond respectively to the circuit components. The method also includes checking correctness of structural connections among the circuit components of the circuit model by traversing the circuit model based on the marked circuit components and checking against preconfigured rules of connectivity among the circuit components.

In some embodiments, a computer system including a processor set, one or more computer-readable storage media, and program instructions stored on the one or more computer-readable storage media to cause the processor set to perform operations including one or more methods described herein also may be provided.

In some embodiments, a computer program including one or more computer-readable storage media and program instructions stored on the one or more storage media to perform operations including one or more methods described herein also may be provided.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 shows an example of a computing environment, which can implement processor structural and connectivity design checks in some embodiments.

FIG. 2 illustrates an example circuit model or design in some embodiments.

FIG. 3 shows traversals of nets in a circuit model in some embodiments.

FIG. 4 is a flow diagram illustrating an overall flow of a method of integration with a structural checking tool.

FIG. 5 shows a class diagram of tag in some embodiments.

FIG. 6 shows a textual representation of tag by way of example in some embodiments.

FIG. 7 shows an actual object definition by way of example in some embodiments.

FIG. 8 illustrates an example connectivity structure between boxes in a circuit model and labels used to mark them in some embodiments.

FIG. 9 illustrates another example of connectivity structure between boxes in a circuit model and labels used to mark them in some embodiments.

FIG. 10 illustrates yet another example of connectivity structure between boxes in a circuit model and labels used to mark them in some embodiments.

FIG. 11 illustrates another example of connectivity structure between boxes in a circuit model and labels used to mark them in some embodiments.

### DETAILED DESCRIPTION

In some embodiments, a method includes loading into computer memory hardware definition language source files for building a circuit model. The method also includes compiling the hardware definition language source files into the circuit model. The method also includes, responsive to the hardware definition language source file loading and compiling, automatically loading into the computer memory, files that define labels for circuit components of the circuit model. The method also includes reading from the files the labels for circuit components. The method also includes marking the circuit components of the circuit model with the labels that correspond respectively to the circuit components. The method also includes checking correctness of structural connections among the circuit components of the circuit model by traversing the circuit model based on the marked circuit components and checking against preconfigured rules of connectivity among the circuit components.

In this way, for example, circuit components can be classified with respect to specific component or net types. For example, this can be achieved by attaching labels to these components (boxes) and nets using an object definition (objDef) file. An objDef file effectively allows to formulate checking rules not only on actual names of circuit components (or nets), but also (if required) on these labels, which serve as an abstraction layer. The design model will change from one version to another in some way. Any potentially required updates on the rules of the checking tool, once they are based on labels, can then be done outside of the tool using the objDef files. For example, consider that a sensor named SENS1 (with the input/output (I/O) net named DATA1), is subsequently named SENS2 (with the I/O net named DATA2). If the rules are rewritten in a onetime task, using labels “sensor” and “data_in” instead of the actual names, the checking tool can handle both versions with a correct objDef file. For instance, instead of a need to map these labels to the old names, the objDef file for the new version (changed names) maps the labels to the new names without any more changes to the checking tool.

One or more of the following features are separable or optional from each other. In some embodiments, the files that define labels for circuit components of the circuit model are written in a formal language, the files being parsed by a computer processor. In this way, for example, a universal format can be provided for all structural checking tools in implementing structural checking rules.

In some embodiments, the files that define labels for circuit components of the circuit model further define properties associated with the circuit components. In this way, for example, additional information can be provided in a generic manner for circuit components across changing circuit models from one design to another.

In some embodiments, the files that define labels for circuit components of the circuit model further define properties associated with the circuit components, the properties including rules that specify structural connections among the circuit components. In this way, for example, structural connections can be specified for use across changing designs.

In some embodiments, the files include labels that specify structural connections among the circuit components, which modify prior built-in rules for checking structural connectivity among the circuit components. In this way, for example, connectivity rules can be modified for circuit components without having to change prior built-in rules.

In some embodiments, the circuit components include combinations of hardware logic gates and nets. In this way, for example, combinations of hardware logic gates and nets can be classified with respect to specific component or net types, effectively replacing (or better enriching) actual names of those hardware logic gates and nets, which are subject to change from one design to another design, with label names. Structural checking rules and properties can be formulated in generic terms, where even if there is a new version, and the same rules should apply also for this new version, both the rules and their implementation need not be updated to include the actual names in the new version of those hardware logic gates and nets.

In some embodiments, the files that define labels for circuit components of the circuit model further define properties associated with the circuit components, the properties including rules that specify structural connections among the circuit components, the rules being extendable to include additional rules. In this way, for example, additional checking rules can be added as needed.

In some embodiments, a computer program product that includes one or more computer-readable storage media and program instructions stored on the one or more storage media to perform operations of methods described herein is also provided.

In some embodiments, a computer system including a processor set, one or more computer-readable storage media, and program instructions stored on the one or more computer-readable storage media to cause the processor set to perform operations of methods described herein is also provided.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as processor structural and connectivity design checks code 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

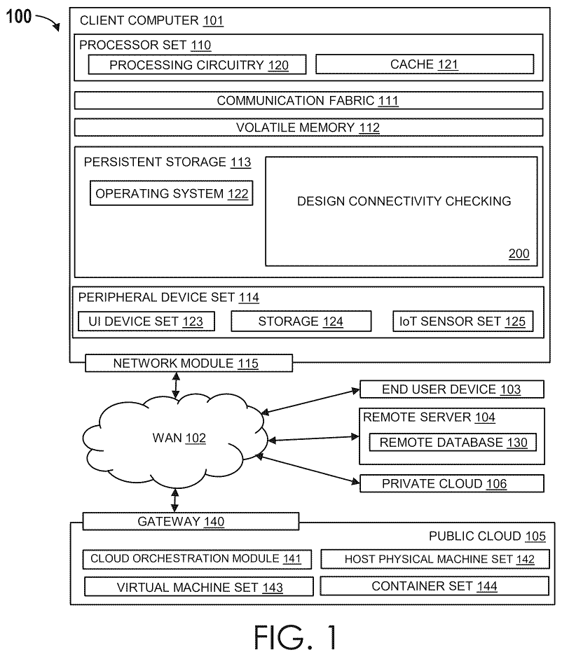

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output nets and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

In various embodiments, systems, methods and techniques that can provide a formal way to specify rules for hierarchical design connectivity checking of circuit components and their I/O nets are disclosed. In some embodiments, the hierarchical design connectivity checking disclosed here can be automatically utilized by different circuit verification tools.

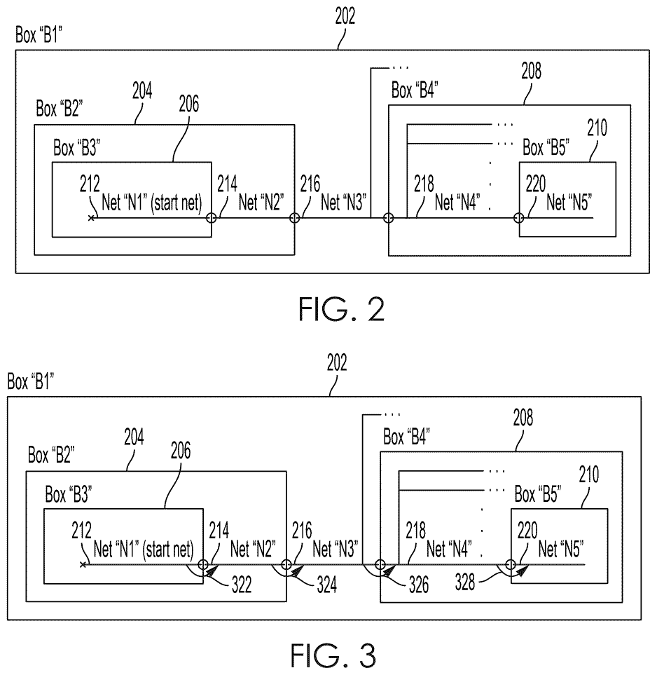

Circuit traversal is a basic function for any structural checking tool. A structural checking tool for a circuit design verifies that the circuit was assembled correctly. A hardware description language (HDL) can be used to generate a structural circuit model. FIG. 2 illustrates an example circuit model or design in some embodiments. This model can be represented as a hierarchical combination of nets and boxes. A box refers to one or more electronic or circuit components. A net is a connecting signal or wire that connects boxes. The representation of a hierarchical circuit model using nets and boxes is also called a netlist. A box can be primitive or complex. A primitive box is the smallest logic function available, e.g., a logical AND or OR, or a simple level-sensitive storage element. Primitive boxes have no HDL file attached to them, as they are “atomic”. A complex box (e.g., 202, 204, 206, 208, 210) can correspond to a hierarchical level usually defined by a hardware description language entity such as Very High Speed Integrated Circuit Hardware Description Language (VHDL) or Verilog entity, and nets (e.g., 212, 214, 216, 218, 220) represent the connecting signals and/or wires. A box can be an HDL's entity, e.g., an entity defined by an HDL file. Briefly, a hardware description language can model a digital system's structure and/or behavior, ranging from the system level down to that of logic gates, e.g., behavior AND/OR structure of digital circuits or integrated circuits (ICs).

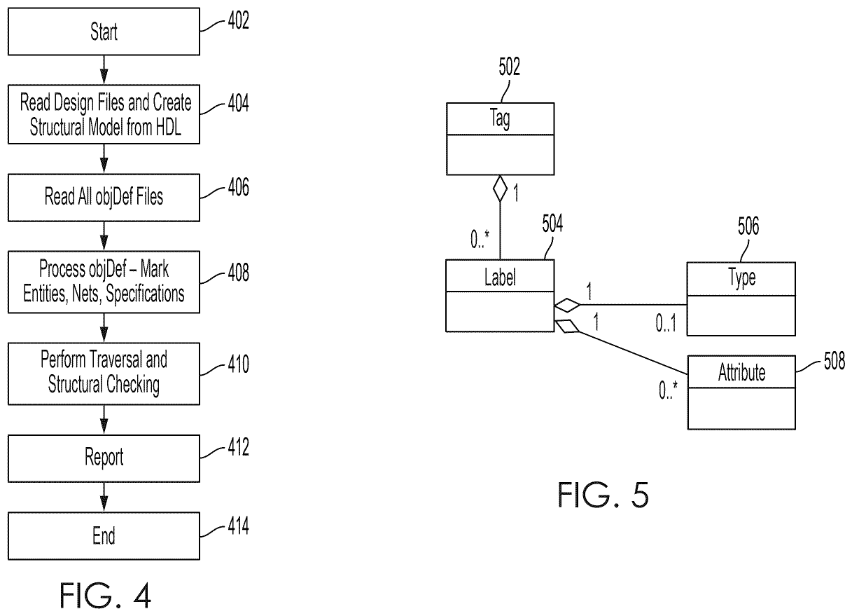

A structural checking tool performing its intended design checks, examines the circuit model. This is done by stepping from net to net. FIG. 3 shows traversals of nets in a circuit model in some embodiments. Any traversal from start to end forms a path. To perform design checking, a structural tool can perform multiple traversals, thus checking over multiple paths. Stepping from net to net is shown by arrows 322, 324, 326, 328, forming a forward traversal path. For example, a structural tool traverses a hierarchical netlist stored in a database. By way of example, one or more netlists in the database are constructed by an HDL compiler that reads and acts on HDL text files. This is shown in FIG. 4 at 404, described below.

For a structural checking tool to perform an effective checking during a traversal, it needs to identify certain complex boxes (e.g., 202, 204, 206, 208, 210) and certain nets (e.g., 212, 214, 216, 218, 220). For example, there can be a rule defining that a controller of name CTRL1 can drive a sensor of name SENS1 only. Also, a controller I/O net named DATA may only connect to a I/O net of a sensor with the exact same name (DATA). Formulating the rules in this rather direct way using explicit names will work, but it has disadvantages. Whenever there is a new version of, e.g., a sensor named SENS2, with the I/O net named DATA2, and the same rules should apply also for this new version, both the rules and their implementation in the checking tool have to be updated to include the new names SENS2 and DATA2.

New and/or modified names of boxes and nets during the development of a design are very common. In some embodiments, the techniques disclosed herein overcome the need to explicitly change affected rules in the checking tool, by including an abstract or general formalization of the rules using symbolic representation of the boxes and nets. In some embodiments, the direct and explicit reference to boxes and nets by their names are replaced by, e.g., a 2-step approach, using an intermediate level of a symbolic representation. This intermediate layer is built by labels. Rules in the checking tool can now be formulated using labels instead of actual names for nets and boxes. The labels provided in objDef-files are referring to actual box and net names in the same file (in the presented format, also in the same line), comprising the mentioned 2-step reference approach. These objDef-files are specific to a single design component (box) type. Such specification file is referred to herein as “objDef-file” or “objDef-files”. However, it should be understood that any other name or naming convention can be used. For example, “objDef-file” or “objDef file” is a term to denote a file that is used to specify properties on HDL entities (e.g., the box itself and the Input/Output (I/O) nets). A computer processor parses this file to extract the user written specification, and hence the file follows a formal language. This objDef file is able to effectively specify properties of HDL entities and their I/O nets. These properties in turn define and/or modify the rules the structural tool enforces on the hierarchical structural netlist model (or circuit model). The rules then determine whether or not a connection structure is deemed to be correct. For the checking rules that require information on a box net or on the box itself, an associated HDL entity has a corresponding objDef-file that specifies this information. In some embodiments, this is achieved by labels on individual nets and on the box itself, as will be further described below. In some embodiments, labels in objDef-files can even manipulate the rules or checking on the connections to the I/O net or box, e.g., the expected polarity of an I/O net and whether a path can be staged via latches or should be directly connected.

In some embodiments, the techniques disclosed herein provide a formal language that abstracts, e.g., provides a representation of, or a universal formal format of, the information from the HDL names to the labels, which a checking tool understands. The objDef-file using this language generally marks every instance of the HDL entity found in the hierarchical circuit model with the given labels on the specified nets and boxes (e.g., performed at 408 of FIG. 4 described below). In some embodiments, objDef files cause labels to be placed at nets and/or boxes in the netlist(s) of the database. For example, in some embodiments, the techniques disclosed herein perform marking, to classify boxes and nets with respect to a specific component or net type by associating labels to them. This replaces (or better enrich) entity or box names (actual names or values) of a circuit model with label names. The former are subject to change from one design to another, the latter can be kept identical over design changes. For example, instead of HDL names of a box and its nets in a rule, labels are used and when needed mapped or associated to actual HDL implementation names using the object definitions or mappings found in the corresponding specification files, e.g., objDef-file.

In some embodiments, a formal language (e.g., objDef-short for object definition, written in a given format or formalistic way for specifying labels for boxes, nets, and their properties) can be integrated with structural checking tools to serve as a universal formal format for marking boxes and nets by labels. The set of labels (the tag) associated to the boxes and nets by the objDefs files can serve two purposes. First is to write the rules in an abstract way when box and net names are referenced in the checking tool. Second is to control the rules itself: select a specific rule if multiple rules are available in a given context, or modify the selected rule. For example, net “X” of a box “ABC” should have two staging latches before reaching the receiver required by some rule. In some embodiments, techniques disclosed herein use a file (e.g., referred to as objDef file) to specify such specifications for different objects using labels. Marking is the process of associating or attaching the labels (e.g., read from objDef file(s)) to the boxes and nets in the hierarchical structural netlist model loaded in the processor memory. FIG. 4 is a flow diagram illustrating an overall flow of a method of integration with a structural checking tool. A computer processor or a processor set can be caused to perform (e.g., via computer instructions) the method in some embodiments. At 402, the flow begins.

At 404, given input such as design files (e.g., HDL files, e.g., VHDL, Verilog, System Verilog files), a processor set is caused to read the given input files or HDL files and create a circuit model, e.g., a hierarchical structural model, e.g., as a hierarchical netlist. By way of example, HDL files can have extensions such as “.v”, “.vhdl”, “.sv”. Every HDL file defines an entity and creates its own netlist in the hierarchical structural netlist model. Thus, an “entity” is defined by an HDL file, which in turn creates a netlist in the structural model. By some HDL files referring to other HDL files, a created netlist can refer to another netlist, hence the hierarchy among the structural netlist model is defined. The resulting structural model reflects the inherent structure (connectivity) among the primitive components like logic gates (AND, OR, XOR), primitive (level-sensitive) storage elements and complex entities. Complex entities (for example, an edge-triggered Latch, or even a complete functional unit) are represented by a netlist compiled as defined by an HDL file. Again here, they may contain basic components or complex components. Complex components refer to (hierarchical) structural netlists. The internal representation of the structural model in the processor set memory is a database-like binary representation to achieve a minimal memory footprint, but any other efficient storage form may be used. For example, this processing step can include loading into computer memory hardware definition language source files for building a circuit model. This processing step can also include compiling the hardware definition language source files into the circuit model.

At 406, the processor set is caused to read object definition files and obtain object definitions (objDefs) associated with the entities identified at 404. The object definition files can also be given or specified. Object definition files are files that define labels for circuit components of the circuit model. These files also can define properties about those circuit components. FIG. 7 shows an example of an objDef file. By way of example, an objDef file can have an extension such as “*.objDef”. As an example of “object definition”, “ABIST_SEL”, which is an actual net name in the netlist is mapped to “abist_ary_sel” which is an abstract label later used to mark nets or boxes. Similarly, “stg::rel_earlier1” tells that this specific net has 1 less staging latches when compared to other inputs. The type of definitions that can be created are flexible and additional definitions can be created. In some embodiments, the objDef files are created by a user, and given to the processor set. For example, this processing step can include, responsive to the hardware definition language source file loading and compiling, automatically loading into the computer memory, files that define labels for circuit components of the circuit model. This processing step can also include reading from the files the labels for circuit components.

At 408, the processor set is caused to process objDef files, e.g., mark entities, boxes and/or nets. For example, the nets (or the box of this entity) referenced by an objDef file content (obtained at 406) are marked with the specified labels. In some embodiments, the processor set is caused to mark the boxes and nets for every instance of an HDL entity in the hierarchical netlist with labels identified in such an objDef file. In some embodiments, the markings caused by processing an objDef file are stored in a database along with the netlist information next to the nets and boxes. In some embodiments, the markings are additive, no original name is removed or replaced. In some embodiment, connectivity rules also can be specified (selected and/or modified) via objDef files. For instance, the type of connection required for certain entity I/O nets are defined by the labels specified in the objDef files. For example, to specify a net can have multiple fan-outs, one can add a label as “conntype::p2m”, compared to a net with no fan-outs “conntype::p2p”. Based on such properties specified in the objDef file, the structural checking tool then ensures the hierarchical structural netlist model does comply with these requirements. This processing step can include marking the circuit components of the circuit model with the labels that correspond respectively to the circuit components.

At 410, the processor set is caused to perform traversal and structural checking of the design specification. For example, a structural checking tool traverses the netlist (e.g., circuit model), for example, described with reference to FIG. 3. In some embodiments, during this traversal, the structural checking tool performs most of the checking. The checking is performed based on built-in rules of the checking tool. Part of the rules are fixed and expect specific real names of boxes and nets. These fixed rules operate without any objDef files. In addition, there are abstract rules, in which these abstract rules do not check real names of boxes or nets, but instead check that these boxes and nets have certain labels attached, which are provided by the objDef files. Certain label markings, caused by the content of the objDef files, can select or modify the application of (fixed or abstract) rules during traversal. This processing step can include checking correctness of structural connections among the circuit components of the circuit model by traversing the circuit model based on the marked circuit components and checking against preconfigured rules of connectivity among the circuit components. Preconfigured rules can be existing rules associated with the structural connections among the circuit components which should be enforced to ensure the structural correctness of the circuit model.

In some embodiments, the checking tool can reuse its existing method of traversing the netlist. In some embodiments, a parser is implemented and used to parse objDef files and modify the internal hierarchical structural netlist database and/or model with additional abstract information (e.g., labels as markings of boxes and nets). The checking tool accesses this extended information in the database or model as needed to modify its already existing rules for checking.

At 412, the processor set is caused to generate a report of a result of the traversal and structural checking performed at 410. At 414, the flow ends.

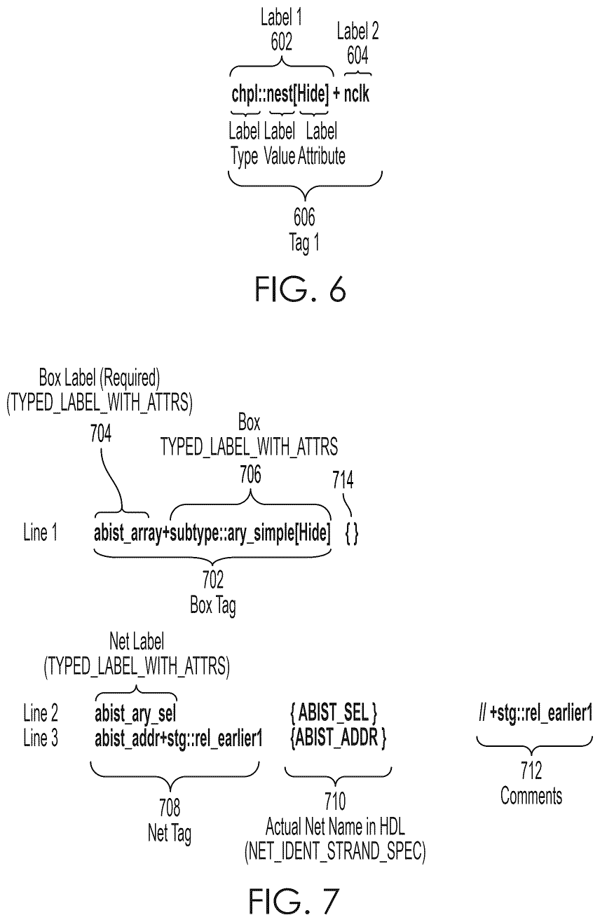

In some embodiments, the syntax or format of objDef files follows the concept of tags and labels. The elements can be boxes or nets and they are marked using labels. In some embodiments, label is a text string. Boxes and nets can be marked with more than one label. A collection of labels is tag. A tag can hold 1 to n labels, where n is an integer. Each label can optionally have a type. A type in some embodiments, is a free form text subclassification of a label, for example, free form sentence or description. With this mechanism the user can express that only some labels are interesting in a certain context. For example, FIG. 6 provides a definition of a label. In the example shown in FIG. 7, which is a representation of an objDef file, “stg::rel_earlier1” label is interesting only when a staging depth along a path is checked, whereas “subtype::ary_simple[Hide]” is interesting only if a subtype of a box is part of some checking.

A label can optionally have additional attributes. In some embodiments, in contrast to types, a number of attributes can be chosen from a predefined set. Attributes are used to provide a more fine granular control to the meaning of a label. For example, they can be used to pass parameters to the checking tool to prevent pollution of the label space by too many different label names.

In some embodiments, the Unified Modelling Language (UML) is used as notation. FIG. 5 shows a class diagram by way of example in some embodiments. Each rectangle 502, 504, 506, 508 represents a term. The connections between the rectangles express the relations between the terms. In short, it means that a tag 502 can hold 1 to n labels 504, and each label 504 can have 0 or 1 type 506. Furthermore each label 504 can have 0 to n additional attributes 508.

FIG. 6 shows a textual representation of tag in some embodiments. A tag 606 can hold 1 to n labels. The first tag in this example includes two labels 602, 604, i.e., label 1 and label 2. The + sign separates the two labels “chpl::nest” and “nclk” within the first tag. The double colon “::” separates the label type from the label value. In this example, “chpl” is the label type and “nest” is the label value. The “[,]” brackets hold optional attributes which are separated by comma. In this example, there is only one attribute, “Hide”.

Example grammar that defines a rule for parsing objDef files (object definition specification files) is shown below. By way of example, the grammar below is written in the ANother Tool for Language Recognition (ANTLR) syntax and defines the rule for parsing objDef files.

```
mark_list_file
  :
      mark_list* EOF
  ;
mark_list
  :
    (
      IDENT ‘(‘ TYPED_LABEL_WITH_ATTRS (‘+’ TYPED_LABEL_WITH_ATTRS)* ‘)’
    | TYPED_LABEL_WITH_ATTRS (‘+’ TYPED_LABEL_WITH_ATTRS)*
    )
    ‘{‘
      NET_IDENT_STRAND_SPEC*
    ‘}’
  ;
```

By way of example, the rule is called “mark_list_file” which includes a list of “mark_list” followed by the end-of-file (EOF) symbol. Each “mark_list” can have either an identifier before the tag in parenthesis, or only the tag. The tag corresponds to at least one (optionally typed or attributed) label. If there are multiple of these labels, they are separated by the “+” symbol. The entire “mark_list” is then enclosed within curly braces and can have zero or more “NET_IDENT_STRAND_SPEC” elements.

FIG. 7 shows an exemplary objDef file at lines 1 to 3. An objDef-file contains any number of entries of the format “Tag ‘{‘Instance_spec?’}’”. Line 1, the Instance_spec 714 of the first entry is empty, which denotes the tag of the box of this entity. All other entries (Lines 2 and 3 here) have an Instance_spec, which correspond to a net in the respective entity. In some embodiments, these nets are input/output (I/O) nets of this entity. FIG. 7 is an example of an objDef file specifying the marking and properties related to one entity (e.g., box) in the netlist. For the given hierarchical netlist or model, there can be multiple objDef files corresponding to different entities. For example, consider that FIG. 7 is objDef file associated with entity (e.g., box) abistArray2x13 in the netlist. A parser or another functionality running on a processor can read this objDef file and mark all the instances of this entity in the netlist as “abist_array” and put the label “subtype: ary_simple[Hide]” indicating that it is an abist_array of subtype ary_simple. This would be caused by Line 1. Similarly, the parser or another functionality can mark the input-ouput nets associated with this entity (ABIST_SEL and ABIST_ADDR, shown at Lines 2 and 3) as abist_ary_sel and abist_addr respectively, and add additional labels specified in the objDef.

The box tag 702 here includes two labels 704, 706. For instance, as described above, each entry of objDef file is of format “Tag ‘{Instance_spec}’”. If instance_spec is empty as shown in FIG. 7 at Line 1, it indicates that tag corresponds to a box. A net tag 708 includes at least one label and an actual net name 710 in HDL that is being processed. If the objDef file entry contains Instance_spec, which is the actual net name in the netlist, it indicates that tag is a net tag. An object definition file can also include comments 712, e.g., denoted by beginning characters “//”, i.e., text appearing on a line following “//” can be treated as comments.

The techniques described herein presents object definitions for circuit components of a circuit model written in a formal language, which can be integrated with structural checking tools to serve as a universal formal format for marking (boxes and nets) and specification (design rules). For example, as shown in FIG. 7, box label “abist_array” and net labels “abist_ary_sel” and “abist_addr” are markings to mark the boxes and nets in the netlist. Additional labels specified are used to define the specification for the box and nets. For example, “subtype::ary_simple” tells this abist_array is of subtype ary_simple. Similarly, “stg::rel_earlier1” says this net will have staging latches 1 less than other I/O nets in this entity. There can be as many specifications defined as needed.

ObjDef file uses a language that formalizes a way of tagging different HDL entities and their I/O nets ensuring a uniform mapping across changing HDLs from one design to another. The language used in ObjDef file also allows to specify connectivity rules (rules specifying structural connections) for entities and their I/O nets. For example, referring to FIG. 7, a processor can be caused to mark a net with “abist_ary_sel”. This can be used by a connectivity rule that compares the labels from both the start and end-points of a path. Any connection then between boxes causing this rule to be active, will require that the start and end-points have the same labels associated at the actual net I/Os at the path start and end-point.

Similarly, “subtype::ary_simple” specifies that this abist array is of ary_simple subtype, and only a net from an abist engine having this same label can connect to this array (if the respective rule exists in the checking tool). Designer of the HDL entity owns the objDef file of that entity, thus specifying labels (tags) and connectivity rules for I/O nets. Responsive to a verification tool (running on a processor set) loading the HDL source file to a processor set and building the circuit hierarchical model, the verification tool is caused to automatically also load all existing objDef files for the entities, to ensure that connectivity rules specified in objDef files are followed. In some embodiments, the verification tool can be modified or patched to be able to handle the objDef files. In some embodiments, the verification tool reads objDef files and collects all the tags for boxes and nets in the netlist. For example, a verification tool can be augmented with a functionality such as a parser or another functionality to read objDef files and collect all the Tags for boxes and nets in the netlist. A verification tool may be augmented to modify its checking operations based on the objDef file provided information. For example, a verification tool may be modified to control its checking behavior based on the information of the objDef files. Other than the checking behavior based on the information of the objDef files, the functionality in the verification tool that performs the netlist traversal and checking may remain same.

In some embodiments, the language specification syntax follows the following format, e.g., as also described above:

abist_array+subtype::ary_simple+... { }
abist_comp_ena+stg::rel_earlier2 {ABIST_STRESS_ENA}

In some embodiments, line 1 specifies the entity labels. Multiple labels are concatenated using ‘+’ symbol. Another symbol can be used. For example, here the label “abist_array” is the entity type and “subtype::ary_simple” is the label telling that this “abist_array” entity is of “subtype ary_simple”. Labels follow the format of “label_type::label_name”. Subsequent lines in the objDef file specify the net labels and net names. For example, “ABIST_STRESS_ENA” is the actual I/O net name in the VHDL and “abist_comp_ena” is the net label attached to that net and used to control/modify the checking rules within the tool.

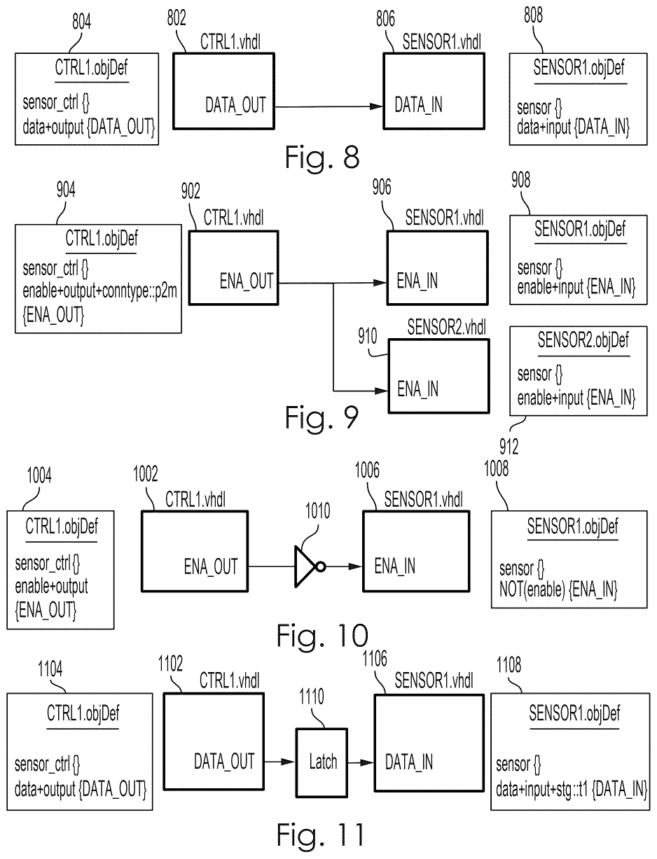

FIG. 8 illustrates a connectivity between “CTRL1” and “SENSOR1” boxes in the netlist and the labels used to mark them in some embodiments. If a rule would require that any path from a “sensor ctrl” to a “sensor” has to have matching I/O net labels (here “data”), then the structure would be accepted by the checking tool. Entity “CTRL1” 802 from netlist is marked as “sensor_ctrl” in objDef 804. Entity “SENSOR1” 806 from netlist is marked as “sensor” in objDef 808. “DATA_OUT” net of CTRL1 802 is marked as “data” and “output” in objDef 804. “DATA_IN” net of SENSOR1 806 marked as “data” and “input” in objDef 808. In this example, Net marked as “data” can only connect to net in other entity marked as “data”.

FIG. 9 illustrates another connectivity structure between boxes in the netlist using object definition (objDef) files in some embodiments. “ENA_OUT” net of CTRL1 902 is marked as “enable”, “output” and “conntype::p2m” using the labels in objDef 904. “SENSOR1” 906 and “SENSOR2” 910 are marked as “sensor” in objDef 908, 912 respectively, and their net “ENA_IN” marked as “enable” in objDef 908, 912 respectively. “conntype::p2m” label in objDef 904 tells that this net can have multiple sinks.

If a rule would require that any path from a “sensor_ctrl” to a “sensor” has to have matching I/O net labels (here “enable”), then the structure (shown in FIG. 9) would be accepted by the checking tool. Another rule might require that multiple receivers are allowed only if the sender has an “conntype::p2m” label. Both the structures shown in FIG. 8 and FIG. 9 would be accepted. The structure shown in FIG. 9 would fail if the “conntype::p2m” label would not be present at the real output name ENA_OUT of CTRL1.

FIG. 10 illustrates another connectivity structure between boxes in the netlist using objDef files in some embodiments. Entity “CTRL1” 1002 from netlist is marked as “sensor_ctrl” and net “ENA OUT” is marked as “enable” in objDef file 1004. Entity “SENSOR1” 1006 from netlist is marked as “sensor” and net “ENA IN” is marked as “enable” in objDef file 1008 with an expected negative polarity. If the same rules exist as in FIG. 9, then the structure shown in FIG. 10 with NOT gate 1010 would be accepted by the checking tool. Note the “NOT (enable)” label in the SENSOR1 objDef 1008. If that would not be present, then the inversion would generate an inversion fail for the path.

FIG. 11 illustrates another connectivity structure between boxes in the netlist using objDef files in some embodiments. Entity “CTRL1” 1102 from netlist is marked as “sensor_ctrl” and net “DATA OUT” marked as “data” using objDef file 1104. Entity “SENSOR1” 1106 from netlist is marked as “sensor” and net “DATA_IN” marked as “data” in objDef file 1108 with an expectation that 1 stage pipeline is expected. If the same rules exist as in FIG. 8, then the structure shown in FIG. 11 would be accepted by the checking tool. In addition, caused by the “stg::t1” label in objDef file 1108, the pipelining depth checks are activated and the length of the pipeline between “sensor_ctrl” and “sensor” is checked for a depth of 1 and deemed to be correct by the checking tool, by the presence latch 1110.

In some embodiments, the following labels and information can be represented in an objDef file for representing HDL entities.

Associating a label (optionally further labels if additional information needs to be associated to this entity) to an HDL entity allows the checking tool and their rules to refer to this abstract label instead of the actual real name of the HDL entity, since HDL entity names can change across different versions of design data over time. This effectively allows different versions of the design without changing the tool, but only adapting the tool external objDef. By way of example, FIG. 8 shows connectivity between label “sensor_ctrl” 802 and label “sensor” 804.

Associating a label (optionally further labels if additional information needs to be associated) to an I/O net in the HDL entity allows the checking tool and their rules to refer to this abstract label instead of the actual real name of the HDL net. Again, this effectively allows different versions of the design without changing the tool, only adapting the external objDef file.

Connectivity Type: These types of labels on the I/O nets classify the kind of connection the checking tool should require for the connections from this I/O net. For example, it may specify that the output net may drive either one single sink or many sinks. Any other kind of connectivity, for example an optionally OR-ing of drivers, or AND-ing can be selected by newly created labels. The only dependency is to update the checking tool to understand the meaning of these “connectivity-controlling” labels.

Polarity: The notation of “NOT (<some-labels>)” requires that the polarity of a connection will be inverted. If this is missing, a non-inverted polarity is expected. It can be set for input or output nets. FIG. 10 illustrates a use case to specify that a path between start and end-point needs to be inverting.

Pipeline or staging information: This information helps to identify if the I/O net connection hops over latches, impacting the timing, or if no staging latches are allowed. If pipelining is allowed, the structural checking or verification tool will require that all connections between two instances have the same staging depth. One may create a label allowing pipelining, but disable the requirement to have all connections of the same depth. FIG. 11 illustrates an example of specifying the required pipeline depth along a connection between two boxes (e.g., 1102 and 1106). Addition labels with associated additional rules in the checking tool can be defined, and therefore the checking is very flexible and easy to specify.

Gating and/or fencing Information: A specific label on an input net can specify if a connection is not allowed, allowed, or even required to have a fencing logic gate in the connection structure from a driving entity output net.

The above described labels or label types and names are provided as examples only. One may create another label which requires, triggers and/or modifies a rule of the checking tool reading in the objDef.

ObjDef file uses language that formalizes the specification of connectivity rules across HDL entities and their I/O nets. These rules can be automatically selected or modified and then executed by the structural verification tool. For example, a structural verification tool can use objDef files as a way to mark entities and its I/O nets with labels (tags) and also specific connectivity rules for every I/O net, which are then automatically checked during netlist traversal. In some embodiments, objDef file provides a flexibility of forming any new specification that needs to be checked.

Multiple hardware definition language (HDL) files can specify a hardware circuit design to be built. A HDL compiler can load these files and create an internal hierarchical structural netlist model in a computer processor memory. A structural checking tool can be run on this model subsequently to verify whether the model adheres to a set of rules defined in this checking tool.

The techniques described herein present a formal way to be able to specify the checking rules in an external way at any level of hierarchy of the hierarchical model. This can be achieved by inserting an abstract symbolic layer of specification, called labels. This layer is in between the actual box and net names in the model and the rules of the checking tool. This label layer is defined in what is referred to as objDef files, in where these labels are associated to actual boxes and I/O nets on any required level of the hierarchical model.

The actual verification of the model by the structural checking tool uses netlist traversal techniques and application of rules. With the symbolic labels now present in the model, the rules can be controlled and/or modified by the labels, and actual box and net name checks can be replaced by checking for symbolic label names.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in some embodiments” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
loading into computer memory hardware definition language source files for building a circuit model;
compiling the hardware definition language source files into the circuit model;
responsive to the hardware definition language source file loading and compiling, automatically loading into the computer memory, files that define labels for circuit components of the circuit model;
reading from the files the labels for circuit components;
marking the circuit components of the circuit model with the labels that correspond respectively to the circuit components; and
checking correctness of structural connections among the circuit components of the circuit model by traversing the circuit model based on the marked circuit components and checking against preconfigured rules of connectivity among the circuit components.

2. The method of claim 1, wherein the files that define labels for circuit components of the circuit model are written in a formal language, the files being parsed by a computer processor.

3. The method of claim 1, wherein the files that define labels for circuit components of the circuit model further define properties associated with the circuit components.

4. The method of claim 1, wherein the files that define labels for circuit components of the circuit model further define properties associated with the circuit components, the properties including rules that specify structural connections among the circuit components.

5. The method of claim 1, wherein the files include rules that specify structural connections among the circuit components, which modify prior built-in rules for checking structural connectivity among the circuit components.

6. The method of claim 1, wherein the circuit components include combinations of hardware logic gates and nets.

7. The method of claim 1, wherein the files that define labels for circuit components of the circuit model further define properties associated with the circuit components, the properties including rules that specify structural connections among the circuit components, the rules being extendable to include additional rules.

8. A computer program product comprising:
one or more computer-readable storage media; and
program instructions stored on the one or more storage media to perform operations comprising:
loading into computer memory hardware definition language source files for building a circuit model;
compiling the hardware definition language source files into the circuit model;
responsive to the hardware definition language source file loading and compiling, automatically loading into the computer memory, files that define labels for circuit components of the circuit model;
reading from the files the labels for circuit components;
marking the circuit components of the circuit model with the labels that correspond respectively to the circuit components; and
checking correctness of structural connections among the circuit components of the circuit model by traversing the circuit model based on the marked circuit components and checking against preconfigured rules of connectivity among the circuit components.

9. The computer program product of claim 8, wherein the files that define labels for circuit components of the circuit model are written in a formal language, the files being parsed by a computer processor.

10. The computer program product of claim 8, wherein the files that define labels for circuit components of the circuit model further define properties associated with the circuit components.

11. The computer program product of claim 8, wherein the files that define labels for circuit components of the circuit model further define properties associated with the circuit components, the properties including rules that specify structural connections among the circuit components.

12. The computer program product of claim 8, wherein the files include rules that specify structural connections among the circuit components, which modify prior built-in rules for checking structural connectivity among the circuit components.

13. The computer program product of claim 8, wherein the circuit components include combinations of hardware logic gates and nets.

14. The computer program product of claim 8, wherein the files that define labels for circuit components of the circuit model further define properties associated with the circuit components, the properties including rules that specify structural connections among the circuit components, the rules being extendable to include additional rules.

15. A computer system comprising:
a processor set;
one or more computer-readable storage media;
program instructions stored on the one or more computer-readable storage media to cause the processor set to perform operations comprising:
loading into computer memory hardware definition language source files for building a circuit model;
compiling the hardware definition language source files into the circuit model;
responsive to the hardware definition language source files loading and compiling, automatically loading into the computer memory, files that define labels for circuit components of the circuit model;
reading from the files the labels for circuit components;
marking the circuit components of the circuit model with the labels that correspond respectively to the circuit components; and
checking correctness of structural connections among the circuit components of the circuit model by traversing the circuit model based on the marked circuit components and checking against preconfigured rules of connectivity among the circuit components.

16. The computer system of claim 15, wherein the files that define labels for circuit components of the circuit model are written in a formal language, the files being parsed by a computer processor.

17. The computer system of claim 15, wherein the files that define labels for circuit components of the circuit model further define properties associated with the circuit components.

18. The computer system of claim 15, wherein the files that define labels for circuit components of the circuit model further define properties associated with the circuit components, the properties including rules that specify structural connections among the circuit components.

19. The computer system of claim 15, wherein the files include rules that specify structural connections among the circuit components, which modify prior built-in rules for checking structural connectivity among the circuit components.

20. The computer system of claim 15, wherein the circuit components include combinations of hardware logic gates and nets.
